(19) United States
(12) Patent Application Publication
(10) Pub. No.: US 2010/0035387 A1
(43) Pub. Date: Feb. 11, 2010

(54) Method for fabricating a CMOS-compatible MEMS device

(76) Inventor: Chia-Shing Chou, Oak Park, CA (US)

Correspondence Address: TOPE-MCKAY & ASSOCIATES, 23852 PACIFIC COAST HIGHWAY #311, MALIBU, CA, 90265, US

(21) Appl. No.: 12/386,001

(22) Filed: Apr. 10, 2009

Related U.S. Application Data
(60) Provisional application No. 61/123,799, filed on Apr. 10, 2008.

(51) Int. Cl. H01L 21/8232; H02N 11/00

(52) U.S. Cl. 438/142; 310/300; 257/E21.615

(57) ABSTRACT

A method for fabricating a CMOS-compatible MEMS device is disclosed. In particular, disclosed is a method of ordering the acts in the fabrication process of the two device types such that one device type will not be damaged by the fabrication process of the other device type. One aspect of the method involves first depositing a masking layer over a portion of a substrate layer to isolate areas for the formation of a second device type. The first device type is then fabricated on the unmasked portion of the substrate. A first device is then protected by depositing a masking layer over the first device. Next, a portion of the masking layer over the substrate is removed to expose areas to form a second device type. The second device type is then fabricated on the unmasked portion of the substrate. Finally, the masking layer over the first device type is removed.

### PRIORITY CLAIM

The present application is a non-provisional patent application, claiming the benefit of priority of U.S. Provisional Application No. 61/123,799, filed on Apr. 10, 2008, entitled, “METHOD FOR FABRICATING A CMOS-COMPATIBLE MEMS DEVICE.”

### BACKGROUND OF INVENTION

(1) Field of Invention

The present invention relates to a method for fabricating a CMOS-compatible MEMS device and, in particular, to a method of ordering the acts in the fabrication process of the two device types such that one device type will not be damaged by the fabrication process of the other device type.

(2) Discussion

Micro-Electro-Mechanical Systems (MEMS) devices in various forms are well-known in the art. U.S. Pat. No. 5,121,089 to Larson (1992) describes an example of a MEMS device in which the armature rotates symmetrically about a post. Larson also suggested cantilevered beam MEMS devices in “Microactuators for GaAs-based microwave integrated circuits,” by L. E. Larson et al., Journal of the Optical Society of America B, 10, 404-407 (1993).

Complementary metal-oxide-semiconductor (CMOS) devices are a major class of integrated circuits. CMOS technology is used in microprocessors, microcontrollers, static random access memory (SRAM), and other digital logic circuits. CMOS technology is also used for a wide variety of analog circuits such as image sensors, data converters, and highly integrated transceivers for many types of communication. CMOS technology was first patented in U.S. Pat. No. 3,356,858 to Wanlass (1967).

Fabrication of both MEMS and CMOS devices requires deposition of multiple layers of material under different process conditions. Some acts require the use of high temperatures or pressures which may damage more delicate components present during that time. For example, some of the fabrication acts in the formation of CMOS devices occur at relatively high temperatures which may damage the components of an existing MEMS device, if present.

Therefore, a continuing need exists for a method of fabricating CMOS and MEMS devices on the same substrate such that one device type will not be damaged by the fabrication of the other device type.

### SUMMARY OF INVENTION

The present invention relates to a method for fabricating a CMOS-compatible MEMS device and, in particular, to a method of ordering the acts in the fabrication process of the two device types such that one device type will not be damaged by the fabrication process of the other device type.

The present invention has four principal aspects. In the first principal aspect, one device type is completely formed before the other. In the second principal aspect, the two device types are formed simultaneously. And in the third principal aspect, a first device type is partially formed, then the second device type is formed, and then the first device type is completed. The fourth principle aspect, as can be appreciated by one skilled in the art, is a CMOS-compatible MEMS device formed by the aforementioned methods. The four principal aspects of the present invention, as well as other aspects, are further described below.

In one aspect of the method of the present invention, one device type is formed before the other. The method involves first depositing a masking layer over a portion of a substrate layer to isolate areas on which to form a second device type. The first device type is then fabricated on the unmasked portion of the substrate. A first device is then protected by depositing a masking layer over the first device. Next, a portion of the masking layer over the substrate is removed to expose areas that were reserved for a second device type. The second device type is then fabricated on the unmasked portion of the substrate. Finally, the masking layer over the first device type is removed. By this method, the first device type will not be damaged by the fabrication process of the second device type.

In another aspect, the method just described further comprises an act of connecting the first device with the second device. A non-limiting example of an appropriate connecting method is wire bonding.

In another aspect, the first device type is a CMOS device, and the second device type is a MEMS device.

In yet another aspect, the first device type is a MEMS device, and the second device type is a CMOS device.

In another aspect of the method of the present invention, the CMOS device and the MEMS device are fabricated simultaneously.

In another aspect, the method of the previous paragraph further comprises the act of connecting the CMOS device with the MEMS device. A non-limiting example of an appropriate connecting method is wire bonding.

In a further aspect of the method of the present invention, a first device type is partially formed, then a second device type is formed, and finally the first device type is completed. The method comprises acts of first depositing a masking layer over a portion of a substrate layer to isolate areas for the formation of a second device type. Then, a first portion of the first device type is fabricated on the unmasked portion of the substrate. Next, the first portion of the first device type is protected by depositing a masking layer over the first portion of the first device type. Next, a portion of the masking layer over the substrate is removed to expose areas to form the second device type. Next, the second device type is protected by depositing a masking layer over the second device type. Then, the masking layer over the first portion of the first device type is removed. A second portion of the first device type is then fabricated. Finally, the masking layer over the second device type is removed.

In another aspect, the method of the previous paragraph further comprises the act of connecting the first device type with the second device type. A non-limiting example of an appropriate connecting method is wire bonding.

In yet another aspect, the first device type is a CMOS device, and the second device type is a MEMS device.

In yet another aspect, the first device type is a MEMS device, and the second device type is a CMOS device.

In a further aspect, the CMOS device is a driver chip for increasing the voltage to the MEMS device.

As can be appreciated by one skilled in the art, the present invention also comprises a CMOS-compatible MEMS device formed by the above methods.

### BRIEF DESCRIPTION OF THE DRAWINGS

The objects, features and advantages of the present invention will be apparent from the following detailed descriptions of the various aspects of the invention in conjunction with reference to the following drawings, where:

FIG. 1 is an illustration showing a top view of a MEMS switch for use with the present invention;

FIG. 2 is an illustration showing a side-view cross section of the MEMS switch of FIG. 1;

FIG. 3 is a flow diagram showing the method of the present invention where a first device type is formed before a second device type;

FIG. 4 is a flow diagram showing the method of the present invention where a first device type is partially formed, then a second device type is formed, then the first device type is completed; and

FIG. 5 is an illustration showing a side-view cross section of a CMOS-compatible MEMS device as formed by the method of the present invention.

### DETAILED DESCRIPTION

The present invention relates to a method for fabricating a CMOS-compatible MEMS device and, in particular, to a method of ordering the acts in the fabrication process of the two device types such that one device type will not be damaged by the fabrication process of the other device type. The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of aspects. Thus, the present invention is not intended to be limited to the aspects presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the claims herein is not intended to invoke the provisions of 35 U.S.C. 112, Paragraph 6.

Before describing the invention in detail, a description of various principal aspects of the present invention is provided. Subsequently, an introduction provides the reader with a general understanding of the present invention. Finally, details of the present invention are provided to give an understanding of the specific aspects.

### (1) Principal Aspects

The present invention has four “principal” aspects. The first principle aspect is a method for forming a CMOS-compatible MEMS device in which one device type (either MEMS or CMOS) is formed on the substrate before the other. The second principle aspect is a method for forming a CMOS-compatible MEMS device in which the two device types are formed simultaneously on the substrate. The third principle aspect is a method for forming a CMOS-compatible MEMS device in which a first device type is partially formed on a substrate, then a second device type is formed on the substrate, and then the first device type is completed. The fourth principle aspect, as can be appreciated by one skilled in the art, is a CMOS-compatible MEMS device formed by the aforementioned methods.

### (2) Introduction

The present invention is a method for forming MEMS and CMOS devices monolithically on a substrate. With regard to MEMS devices, any of a variety of MEMS devices known in the art are suitable for use with the methods of the present invention, including but not limited to the devices disclosed in U.S. Pat. No. 6,962,832 to Chia-Shing Chou, entitled “A FABRICATION METHOD FOR MAKING A PLANAR CANTILEVER, LOW SURFACE LEAKAGE, REPRODUCIBLE AND RELIABLE METAL DIMPLE CONTACT MICRO-RELAY MEMS SWITCH,” and U.S. Pat. No. 7,101,724, to Chia-Shing Chou, entitled “MICROELECTROMECHANICAL DEVICE HAVING A COMMON GROUND PLANE LAYER AND A SET OF CONTACT TEETH AND METHOD FOR MAKING THE SAME,” which are both incorporated by reference as though fully disclosed herein.

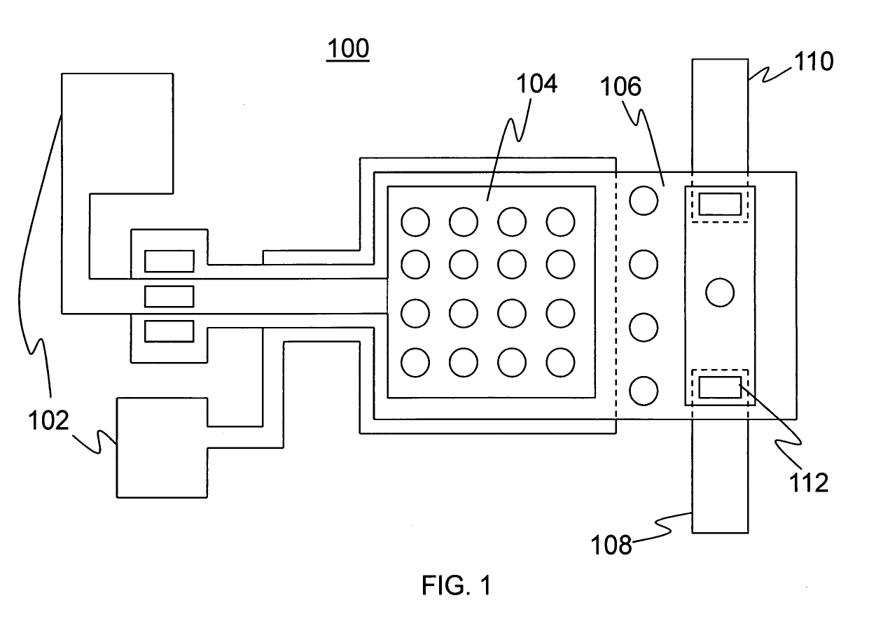

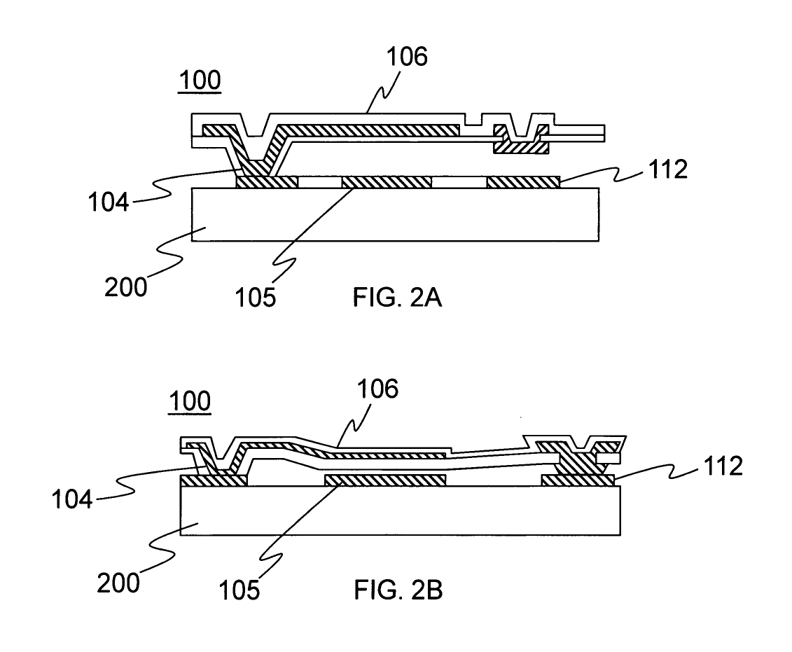

FIG. 1 is an illustration showing a top-down view of a MEMS cantilever device 100 as disclosed in U.S. Pat. No. 6,962,832. FIG. 2A is an illustration showing a cross-sectional view of the same MEMS cantilever device in a “open” position, and FIG. 2B shows a cross-sectional view of a MEMS cantilever device in a “closed” position. The MEMS device comprises two switch control pads 102 (FIG. 1) for activating the switch. An anchor 104 holds the device to the substrate 200 (in FIGS. 2A and 2B). A control electrode 105, when activated, will actuate the cantilever arm 106 from an “open” (FIG. 2A) to a “closed” (FIG. 2B) position. The device 100 further comprises an radio frequency (RF) “in” line 108 and an RF “out” line 110 (FIG. 1). When the device 100 is in “closed” position, an RF contact 112 region bridges the RF “in” 108 and RF “out” 110 lines, allowing for transmission of current during that time. The materials used to construct MEMS devices such as the one shown vary widely, but typical materials comprise high resistivity silicon for the substrate 200 (FIG. 2A), Silicon Nitride for the cantilever arm 106, and gold or another highly conductive material for the contact portions 104, 105, and 112 (FIG. 2A).

Complementary metal-oxide-semiconductor (CMOS) devices are a major class of integrated circuits, including but not limited to driver circuits. Because CMOS is a relatively general class of devices, their designs will vary greatly. However, the basic element of most CMOS devices is a transistor. A transistor is a three-terminal electronic device which can be likened to the basic structure of the MEMS device shown in FIG. 1. Similar to a transistor, control electrode 105, which can be considered like the Gate of a transistor, can be actuated to affect the current running through the two other electrodes 108, 110 (the RF “in” and RF “out” lines).

### (3) Details of the Invention

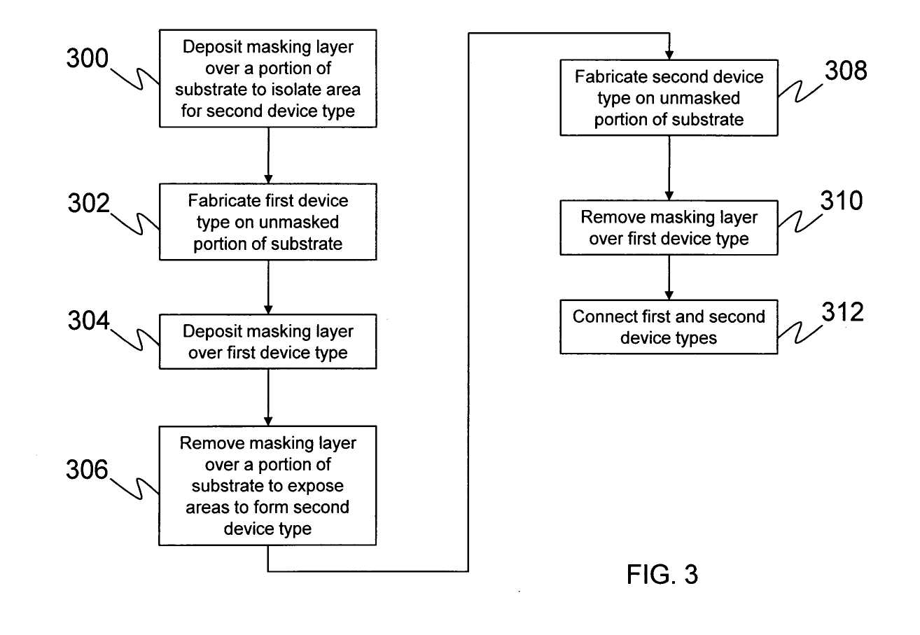

FIG. 3 is a flow diagram showing a method of forming a CMOS-compatible MEMS device in which one device type is formed before the other. Generally, the CMOS component should be the first device type formed, since the CMOS fabrication occurs at much higher temperature than the MEMS device. However, the ordering of acts should be tailored to the specific temperature ranges of the particular devices being fabricated. There may be some instances where the MEMS fabrication process may damage an existing CMOS device, in which case the MEMS device should be fabricated first. It should be noted that certain intermediate steps such as (but not limited to) masking or unmasking portions of devices or substrate need not occur in any particular order, as long as such ordering results in the desired composite structure. The critical acts are those which use extreme process conditions which will damage existing devices. Also, it should be noted that the method of the present invention is readily applicable to other device types besides CMOS, including but not limited to N-channel metal-oxide-semiconductors (NMOS).

The first act of the method shown in FIG. 3 is to deposit 300 a masking layer over a portion of the substrate to isolate an area of the substrate for the fabrication of a second device type later. The substrate can be masked with a variety of materials which have a good differential etch rate with passivation nitride (an example of the protective layer for the first device type), including but not limited to a sacrificial oxide. The sacrificial oxide can be deposited by either plasma-enhanced chemical vapor deposition (PECVD) or as a spin-on glass. The first device type is then fabricated 302 on the unmasked portion of the substrate. As mentioned previously, the first device type will generally be CMOS due to the higher temperatures required to fabricate a CMOS device. The next act is to deposit 304 a masking layer over the first device type in order to protect it. As mentioned previously, this masking layer generally comprises a material similar to a passivation Nitride. When the first device type is protected, the masking layer over the substrate is removed 306 to expose areas to form a second device type. If the masking layer is sacrificial oxide, it can generally be removed with hydrofluoric acid (HF). As can be appreciated by one skilled in the art, under certain fabrication conditions it may be possible to interchange the order of the acts of removing 306 the masking layer from the substrate and the act of depositing 304 a masking layer over the first device type. Next, the second device type is fabricated 308 on the unmasked portion of substrate. Typically the second device type will be the MEMS device, but, as mentioned before, there may be instances where it is desirable to fabricate the CMOS device as the second device. After the second device type is formed, the masking layer over the first device type can then be removed 310 or left intact depending on the method of the connection between the two device types. Finally, the two devices can be connected 312 via techniques known in the art including but not limited to wire bonding.

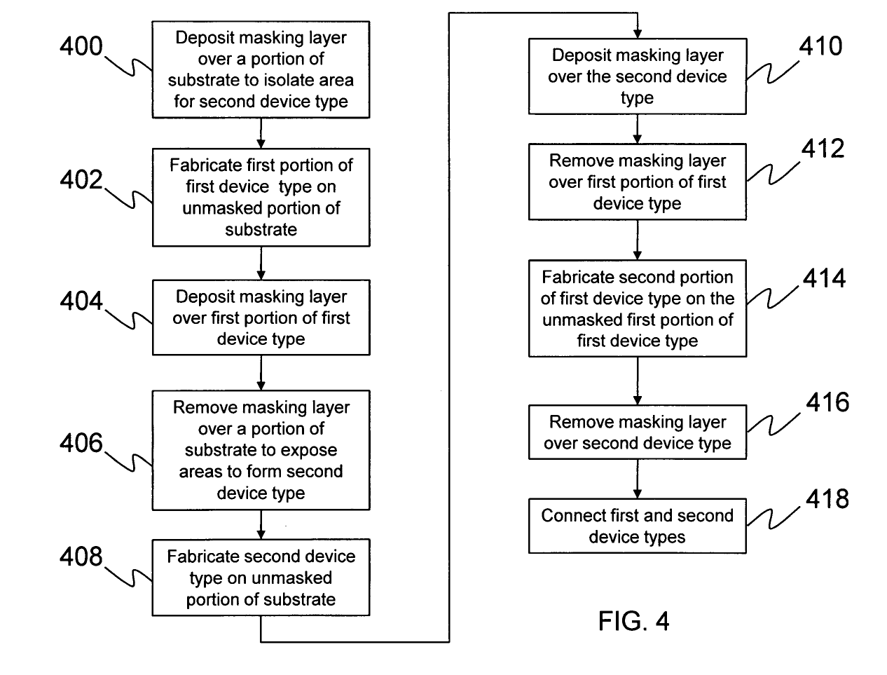

FIG. 4 is a flow diagram showing a method of forming a CMOS-compatible MEMS device where a first device type is partially formed, then a second device type is formed, then the first device type is completed. The first act of the method is to deposit 400 a masking layer over a portion of the substrate to isolate an area for the fabrication of a second device type later. The substrate can be masked with a variety of materials which have a good differential etch rate with passivation nitride (an example of the protective layer for the first device type), including but not limited to a sacrificial oxide. The sacrificial oxide can be deposited by either plasma-enhanced chemical vapor deposition (PECVD) or as a spin-on glass. The next act is to fabricate 402 a first portion of a first device type on the unmasked portion of the substrate. As mentioned previously, in most cases the first device type will be CMOS. A masking layer is then deposited 404 over the first portion of the first device type. As mentioned previously, the masking layer generally comprises a sacrificial oxide. The next act is to remove 406 the masking layer over a portion of the substrate to expose the areas previously isolated to form the second device type. Again, if the masking layer is sacrificial oxide, it can generally be removed with hydrofluoric acid (HF). Also, as mentioned previously and as can be appreciated by one skilled in the art, it may be possible to interchange the order of the acts of removing 306 the masking layer from the substrate and the act of depositing 304 a masking layer over the first portion of the first device type. Next, the second device type is fabricated 408 on the unmasked portion of substrate. As with other aspects of the invention, in this aspect MEMS will generally comprise the second device type formed, as MEMS devices will likely be damaged by some of the fabrication acts in CMOS processes. After the second device type is formed, a masking layer is deposited 410 over the second device type. Then, the making layer over the first portion of the first device type is removed 412, and a second portion of the first device type is fabricated 414 on the unmasked first portion of the first device type, thereby completing the first device type. When the first device type is complete, the masking layer over the second device type is removed 416. Finally, the two devices can be connected 418 via techniques known in the art including but not limited to wire bonding.

In some cases, where the various fabrication temperatures and pressures of the desired devices are mutually compatible, it will be possible to form the two devices simultaneously on the substrate. Forming the devices simultaneously would be beneficial to cut down on both production time and production cost, as it would not be necessary to perform the acts of depositing and removing protective layers. As with previously described aspects of the method of the present invention, the two devices can be connected via techniques known in the art including but not limited to wire bonding.

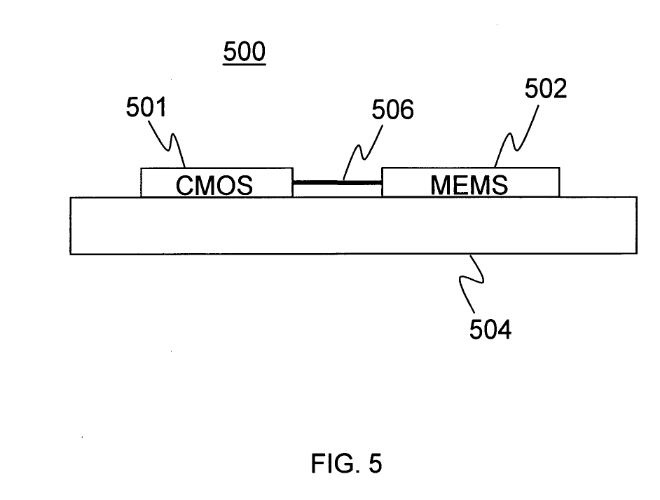

As can be appreciated by one skilled in the art, the present invention also comprises a CMOS-compatible MEMS device formed by the acts of the method of the present invention, as previously described. FIG. 5 is an illustration showing a side-view cross section of a CMOS-compatible MEMS device 500 formed by the methods of the present invention. The figure depicts a CMOS 501 and MEMS 502 device joined monolithically on a substrate 504 via wire bonding 506.

What is claimed are:

1. A method for fabricating a CMOS-compatible MEMS device, the method comprising acts of:
depositing a masking layer over a portion of a substrate layer to isolate areas on which to form a second device type;
fabricating a first device type on the unmasked portion of the substrate;
depositing a masking layer over the first device type;
removing the masking layer over a portion of the substrate layer to expose areas to form the second device type;
fabricating the second device type on the unmasked portion of the substrate; and
removing the masking layer over the first device type,
whereby the second device type will not be damaged by the fabrication process of the first device type.

2. The method of claim 1, further comprising the act of connecting the first device type with the second device type.

3. The method of claim 2, where the first device type and the second device type are connected via wire bonding.

4. The method of claim 1, where the first device type is a CMOS device, and the second device type is a MEMS device.

5. The method of claim 1, where the first device type is a MEMS device, and the second device type is a CMOS device.

6. The method of claim 1, where at least one of the device types is a CMOS device, and the CMOS device is a driver chip.

7. A method of fabricating a CMOS-compatible MEMS device, the method comprising acts of fabricating a CMOS device and a MEMS device simultaneously.

8. The method of claim 7, further comprising the act of connecting the CMOS device with the MEMS device.

9. The method of claim 8, where the CMOS device and the MEMS device are connected via wire bonding.

10. The method of claim 7, where the CMOS device is a driver chip.

11. A method of fabricating a CMOS-compatible MEMS device, the method comprising acts of:
depositing a masking layer over a portion of a substrate layer to isolate areas on which to form a second device type;
fabricating a first portion of a first device type on the unmasked portion of the substrate;
depositing a masking layer over the first portion of the first device type;
removing the masking layer over a portion of the substrate layer to expose areas on which to form the second device type;
fabricating the second device type on the unmasked portion of the substrate;
depositing a masking layer over the second device type;
removing the masking layer over the first portion of the first device type;
fabricating a second portion of the first device type on the unmasked first portion of the first device type; and
removing the masking layer over the second device type,
whereby the second device type will not be damaged by the fabrication process of the first portion of the first device type, and whereby the second portion of the first device type will not be damaged by the fabrication process of the second device type.

12. The method of claim 11, further comprising the act of connecting the first device type with the second device type.

13. The method of claim 12, where the first device type and the second device type are connected via wire bonding.

14. The method of claim 11, where the first device type is a CMOS device, and the second device type is a MEMS device.

15. The method of claim 11, where the first device type is a MEMS device, and the second device type is a CMOS device.

16. The method of claim 11, where at least one of the device types is a CMOS device, and the CMOS device is a driver chip.

17. A CMOS-compatible MEMS device formed by the method of claim 1.

18. A CMOS-compatible MEMS device formed by the method of claim 2.

19. A CMOS-compatible MEMS device formed by the method of claim 7.

20. A CMOS-compatible MEMS device formed by the method of claim 8.

21. A CMOS-compatible MEMS device formed by the method of claim 11.

22. A CMOS-compatible MEMS device formed by the method of claim 12.

23. A CMOS-compatible MEMS device comprising a CMOS device functionally connected with a MEMS device on a common substrate.

24. The device of claim 20, wherein the CMOS device and the MEMS device are functionally connected via wire bonding.
